(19) United States
(12) Patent Application Publication
(10) Pub. No.: US 2025/0359268 A1
(43) Pub. Date: Nov. 20, 2025

(54) SEMICONDUCTOR DEVICE

(71) Applicant: SAMSUNG ELECTRONICS CO., LTD., Suwon-si (KR)

(72) Inventors: Joonyong Kim, Suwon-si (KR); Jongseob Kim, Suwon-si (KR); Jaejoon Oh, Suwon-si (KR); In Jun Hwang, Suwon-si (KR)

(21) Appl. No.: 19/042,482

(22) Filed: Jan. 31, 2025

(30) Foreign Application Priority Data
May 14, 2024 (KR) 10-2024-0063025

(51) Int. Cl. H10D 64/27; H10D 30/01; H10D 30/47; H10D 62/85; H10D 64/00; H10D 64/01

(52) U.S. Cl. CPC H10D 64/411; H10D 30/015; H10D 30/475; H10D 62/8503; H10D 64/01; H10D 64/111

(57) ABSTRACT

An example semiconductor device includes a channel layer, a barrier layer on the channel layer, a gate electrode layer located on the barrier layer and extending in a first direction parallel to an upper surface of the barrier layer, a gate semiconductor layer between the barrier layer and the gate electrode layer, and a source electrode and a drain electrode connected with the channel layer and spaced apart from the gate electrode layer in a second direction parallel to the upper surface of the barrier layer and intersecting the first direction. In a cross-section cut in the second direction and in a third direction perpendicular to the upper surface of the barrier layer, an angle formed by a lower surface and a side surface of the gate electrode layer is greater than an angle formed by a lower surface and a side surface of the gate semiconductor layer.

### CROSS-REFERENCE TO RELATED APPLICATION

This application claims priority to and the benefit of Korean Patent Application No. 10-2024-0063025 filed in the Korean Intellectual Property Office on May 14, 2024, the entire contents of which are incorporated herein by reference.

### BACKGROUND

In modern society, semiconductor devices are closely related to daily life. In particular, the importance of power semiconductor devices used in various fields such as transportation fields such as electric vehicles, railroads, and electric trams, renewable energy systems such as solar power generation and wind power generation, and mobile devices is gradually increasing. Power semiconductor devices are semiconductor devices used to handle high voltage or high current, and perform functions such as power conversion and control in large power systems or high-output electronic devices. Power semiconductor devices have the ability and durability to handle high power, so they can handle large amounts of current and withstand high voltage. For example, power semiconductor devices can handle voltages from hundreds of volts to thousands of volts and currents from tens of amperes to thousands of amperes. Power semiconductor devices can improve the efficiency of electrical energy by minimizing power loss. Additionally, power semiconductor devices can be stably driven even in environments such as high temperatures.

These power semiconductor devices can be classified according to materials, and examples include SiC power semiconductor devices and GaN power semiconductor devices. Power semiconductor devices are manufactured using SiC or GaN instead of existing silicon wafers, and thereby the disadvantage of silicon, which has unstable characteristics at high temperatures, can be compensated. The SiC power semiconductor devices are resistant to high temperatures and have low power loss, and can be suitable for electric vehicles, renewable energy systems, etc. The GaN power semiconductor devices require high costs, but are efficient in terms of speed and can be suitable for high-speed charging of mobile devices.

### SUMMARY

The present disclosure relates to a semiconductor device in which the alignment between the gate electrode layer and the gate semiconductor layer is easy and excellent, a pattern of the gate semiconductor layer is precise, and a degree of freedom in selecting the etch materials for the gate electrode layer and the gate semiconductor layer is increased. Therefore, a problem of defects caused by by-products caused by etching the dissimilar materials of the gate electrode layer and the gate semiconductor layer with different etching materials can be solved. A field between the side of the gate semiconductor layer and the upper surface of the barrier layer can be easily controlled, and voids can be prevented when forming the field dispersion layer.

In some implementations, a semiconductor device includes a channel layer, a barrier layer located on the channel layer and including a material having an energy bandgap different from that of the channel layer, a gate electrode layer located on the barrier layer and extending in a first direction parallel to an upper surface of the barrier layer, a gate semiconductor layer between the barrier layer and the gate electrode layer, and a source electrode and a drain electrode connected to the channel layer and spaced apart from the gate electrode layer in a second direction parallel to the upper surface of the barrier layer and intersecting the first direction, wherein, in a cross-section cut in the second direction and in the third direction perpendicular to the upper surface of the barrier layer, an angle formed by the lower surface and the side surface of the gate electrode layer is greater than an angle formed by the lower surface and the side surface of the gate semiconductor layer.

In some implementations, a semiconductor device includes a channel layer, a barrier layer located on the channel layer and including a material having an energy bandgap different from that of the channel layer, a gate electrode layer located on the barrier layer and extending in a first direction parallel to the upper surface of the barrier layer, a gate semiconductor layer between the barrier layer and the gate electrode layer, a hard mask layer on the gate electrode layer, and a source electrode and a drain electrode connected to the channel layer and spaced apart from the gate electrode layer in a second direction parallel to the upper surface of the barrier layer and intersecting the first direction, wherein, in a cross-section cut in the second direction and in the third direction perpendicular to the upper surface of the barrier layer, an edge formed by the upper surface and side surface of the hard mask layer have a rounded shape, and a length of the lower surface of the gate electrode layer in the second direction is smaller than a length of the upper surface of the gate semiconductor layer in the second direction and a length of the lower surface of the hard mask layer in the second direction.

In some implementations, a method for manufacturing semiconductor device includes forming a channel layer on the substrate, forming a barrier layer on the channel layer including a material having an energy bandgap different from that of the channel layer, sequentially forming a gate semiconductor material layer, a gate electrode material layer, and a hard mask material layer on the barrier layer, forming a photoresist pattern on the hard mask material layer, etching the hard mask material layer and the gate electrode material layer with a first etching gas using the photoresist pattern to form a hard mask layer and a gate electrode layer, removing the photoresist pattern, forming a gate semiconductor layer by etching the gate semiconductor material layer with a second etching gas different from the first etching gas using the hard mask layer, and forming a source electrode and a drain electrode connected to the channel layer and spaced apart from the gate electrode layer.

In the semiconductor device according to some implementations, the alignment between the gate electrode layer and the gate semiconductor layer is easy and excellent, a pattern of the gate semiconductor layer is precise, a degree of freedom in selecting the etch materials for the gate electrode layer and the gate semiconductor layer is increased, a problem of defects caused by by-products caused by etching the dissimilar materials of the gate electrode layer and the gate semiconductor layer with different etching materials can be solved, a field between the side of the gate semiconductor layer and the upper surface of the barrier layer can be easily controlled, and voids can be prevented when forming the field dispersion layer.

### BRIEF DESCRIPTION OF THE DRAWINGS

FIG. 1 is a plan view showing an example of a semiconductor device.

FIG. 2 is an example cross-sectional view taken along line A-A′ in FIG. 1.

FIG. 3 is an example enlarged cross-sectional view of portion P of FIG. 2.

FIG. 4 is an example enlarged cross-sectional view of portion P of FIG. 2.

FIG. 5 is an example enlarged cross-sectional view of portion P of FIG. 2.

FIG. 6 is an example enlarged cross-sectional view of portion P of FIG. 2.

FIG. 7 is an example enlarged cross-sectional view of portion P of FIG. 2.

FIGS. 8, 9, 10, 11, 12, 13, and 14 are cross-sectional views showing an example of a method of manufacturing a semiconductor device according to process sequence.

### DETAILED DESCRIPTION

Hereinafter, the present disclosure will be described more fully hereinafter with reference to the accompanying drawings, in which example implementations of the present disclosure are shown. As those skilled in the art would realize, the described implementations may be modified in various different ways, all without departing from the spirit or scope of the present disclosure.

The drawings and description are to be regarded as illustrative in nature and not restrictive. Like reference numerals designate like elements throughout the specification.

The size and thickness of each constituent element as shown in the drawings are randomly indicated for better understanding and ease of description, and this disclosure is not necessarily limited to as shown. In the drawings, the thickness of layers, regions, etc., are exaggerated for clarity. In addition, in the drawings, for better understanding and ease of description, the thickness of some layers and areas is exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means being disposed on or below the object portion, and does not necessarily mean being disposed on the upper side of the object portion based on a gravitational direction.

In addition, unless explicitly described to the contrary, the word “comprise,” and variations such as “comprises” or “comprising,” will be understood to imply the inclusion of stated elements but not the exclusion of any other elements.

In addition, in this specification, the phrase “on a plane” means viewing a target portion from the top, and the phrase “on a cross-section” means viewing a cross-section formed by vertically cutting a target portion from the side.

In addition, throughout the specification, two directions parallel to and intersecting the upper surface of the substrate are defined as the first direction D1 and the second direction D2, respectively, and the direction perpendicular to the upper surface of the substrate is described as the third direction D3. For example, the first direction D1 and the second direction D2 may be perpendicular to each other.

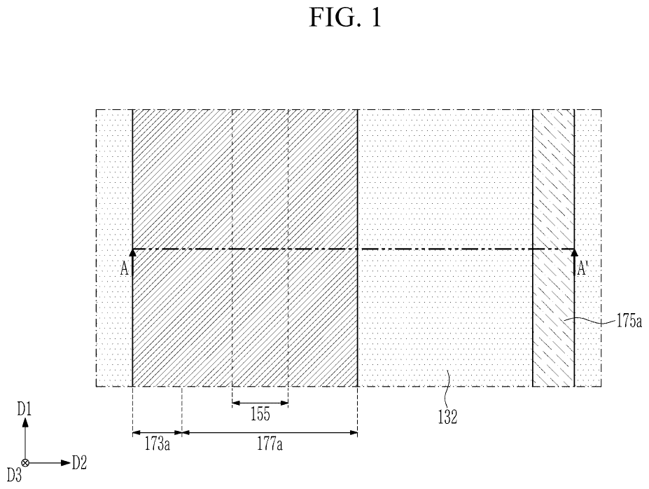

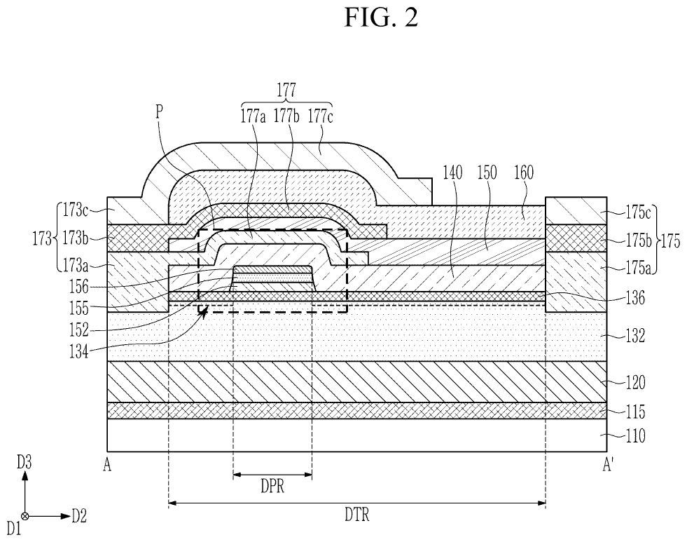

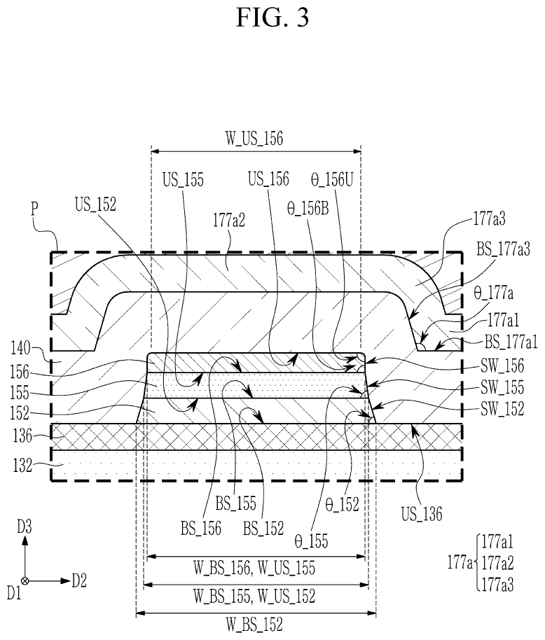

FIG. 1 is a plan view showing an example of a semiconductor device. FIG. 2 is an example cross-sectional view taken along line A-A′ in FIG. 1. FIG. 3 is an example enlarged cross-sectional view of portion P of FIG. 2.

For clear understanding and simplified illustration, FIG. 1 mainly shows the channel layer 132, the gate electrode layer 155, the lower source electrode 173a, the first field dispersion layer 177a, and the lower drain electrode 175a.

Referring to FIGS. 1 to 3, a semiconductor device includes a channel layer 132, a barrier layer 136 on the channel layer 132, and a gate electrode layer 155 on the barrier layer 136, a gate semiconductor layer 152 between the barrier layer 136 and the gate electrode layer 155, and a source electrode 173 and a drain electrode 175 on both sides of the gate electrode layer 155 and connected to the channel layer 132.

The channel layer 132 is a layer that forms a channel between the source electrode 173 and the drain electrode 175 and a two-dimensional electron gas (2DEG, 2-dimensional electron gas) 134 may be located inside the channel layer 132. The two-dimensional electron gas 134 refers to a group of electrons that can move freely in two dimensions (e.g., in an x-y plane direction) as a charge transport model used in solid physics, but cannot move and are tightly bound in another dimension (e.g., in a z direction). In other words, the two-dimensional electron gas 134 may exist in a two-dimensional paper-like form within a three-dimensional space. This two-dimensional electron gas 134 mainly appears in a semiconductor heterojunction structure, and may occur at the interface between the channel layer 132 and the barrier layer 136 in the semiconductor device. For example, the two-dimensional electron gas 134 may be generated in the portion closest to the barrier layer 136 within the channel layer 132.

The channel layer 132 may include nitride including Group III-V materials, for example, Al, Ga, In, B, or a combination thereof. The channel layer 132 may be made of a single layer or multiple layers. As an example, the channel layer 132 may include AlₓIn_{y}Ga_{1-x-y}N (0≤x≤1, 0≤y≤1, x+y≤1). For example, the channel layer 132 may include AlN, GaN, InN, InGaN, AlGaN, AlInN, AlInGaN, or a combination thereof. The channel layer 132 may be a layer doped with impurities or a layer undoped with impurities. A thickness of the channel layer 132 may be about several hundred nm or less.

The channel layer 132 may be located on the substrate 110, and a seed layer 115, or a buffer layer 120 may be located between the substrate 110 and the channel layer 132. The substrate 110, the seed layer 115, and the buffer layer 120 are layers necessary to form the channel layer 132, and may be omitted in some cases. For example, when a substrate made of GaN is used as the channel layer 132, at least one of the substrate 110, the seed layer 115, and the buffer layer 120 may be omitted. Considering that the price of a substrate made of GaN is relatively high, the channel layer 132 including GaN can be grown using the substrate 110 made of Si. At this time, as the lattice structure of Si and GaN are different, it may not be easy to grow the channel layer 132 directly on the substrate 110. Accordingly, the seed layer 115 and the buffer layer 120 can be first grown on the substrate 110, and then the channel layer 132 can be grown on the buffer layer 120. Additionally, at least one of the substrate 110, the seed layer 115, and the buffer layer 120 may be removed from the final structure of the semiconductor device after being used in the manufacturing process.

The substrate 110 may include a semiconductor material. For example, the substrate 110 may include sapphire, Si, SiC, AlN, GaN, or a combination thereof. The substrate 110 may be a silicon on insulator (SOI) substrate. However, the material of the substrate 110 is not limited to this, and any commonly used substrate can be applied. In some cases, the substrate 110 may include an insulating material. For example, several layers, including the channel layer 132, may be first formed on a semiconductor substrate, then the semiconductor substrate may be removed and replaced with an insulating substrate.

The seed layer 115 may be located on the substrate 110. The seed layer 115 may be located directly on the substrate 110. However, it is not limited to this, and another predetermined layer may be further located between the substrate 110 and the seed layer 115. The seed layer 115 is a layer that serves as a seed for growing the buffer layer 120, and may be made of a crystal lattice structure that serves as a seed for the buffer layer 120. For example, the seed layer 115 may include AlN, but is not limited thereto.

The buffer layer 120 may be located on the seed layer 115. The buffer layer 120 may be located directly on the seed layer 115. However, it is not limited to this, and another predetermined layer may be further located between the seed layer 115 and the buffer layer 120. The buffer layer 120 may be located between the seed layer 115 and the channel layer 132. The buffer layer 120 may include nitride including Group III-V materials, for example, Al, Ga, In, B, or a combination thereof. The buffer layer 120 may include AlₓIn_{y}Ga_{1-x-y}N (0≤x≤1, 0≤y≤1, x+y≤1). For example, the buffer layer 120 may include AlN, GaN, InN, InGaN, AlGaN, AlInN, AlInGaN, or a combination thereof. The buffer layer 120 may be made of a single layer or multiple layers. For example, the buffer layer 120 may include a superlattice layer and a high-resistance layer.

The superlattice layer alleviates a difference in lattice constant and thermal expansion coefficient between the substrate 110 and the channel layer 132, thereby relieving tensile stress and compressive stress generated between the substrate 110 and the channel layer 132. The high-resistance layer may be used to prevent the semiconductor device from being deteriorated by preventing leakage current from flowing through the channel layer 132. To this end, the high-resistance layer may be made of a low-conductivity material to electrically insulate the substrate 110 and the channel layer 132.

The barrier layer 136 may be located on the channel layer 132. The barrier layer 136 may be located directly on the channel layer 132. However, it is not limited to this, and another predetermined layer may be further located between the channel layer 132 and the barrier layer 136. A region of the channel layer 132 that is overlapped with the barrier layer 136 may be a drift region DTR. The drift region DTR may be located between the source electrode 173 and the drain electrode 175. When a potential difference occurs between the source electrode 173 and the drain electrode 175, carriers may move in the drift region DTR. The semiconductor device may be turned on/off depending on whether a voltage is applied to the gate electrode layer 155 and the magnitude of the voltage applied to the gate electrode layer 155. When a voltage greater than the threshold voltage is applied to the gate electrode layer 155 and the semiconductor device is turned on, a channel may be created in the depletion region DPR. Accordingly, movement of the carrier may occur in the drift region DTR. If a voltage lower than the threshold voltage is applied to the gate electrode layer 155 or no voltage is applied, the channel path may be blocked in the depletion region DPR and carrier movement may not occur.

The barrier layer 136 may include nitride including Group III-V materials, for example, Al, Ga, In, B, or a combination thereof. The barrier layer 136 may include AlₓIn_{y}Ga_{1-x-y}N (0≤x≤1, 0≤y≤1, x+y≤1). For example, the barrier layer 136 may include AlN, GaN, InN, InGaN, AlGaN, AlInN, AlInGaN, or a combination thereof. The energy bandgap of the barrier layer 136 can be adjusted by a composition ratio of Al or In. The barrier layer 136 may be doped with a predetermined impurity. At this time, the impurity doped into the barrier layer 136 may be a p-type dopant that can provide holes. For example, the impurity doped into the barrier layer 136 may be magnesium (Mg). By increasing or decreasing the impurity doping concentration of the barrier layer 136, the threshold voltage, on-resistance, etc. of the semiconductor device can be adjusted.

The barrier layer 136 may include a semiconductor material having different characteristics from the channel layer 132. The barrier layer 136 may be different from the channel layer 132 in at least one of polarization characteristics, energy bandgap, and lattice constant. For example, the barrier layer 136 may include a material having a different energy bandgap than the channel layer 132. At this time, the barrier layer 136 may have a higher energy bandgap than the channel layer 132 and may have a higher electrical polarization rate than the channel layer 132. The two-dimensional electron gas 134 may be induced in the channel layer 132, which has a relatively low electrical polarization rate, by the barrier layer 136. In this regard, the barrier layer 136 may also be called a channel supply layer or a two-dimensional electron gas supply layer. The two-dimensional electron gas 134 may be formed within the portion of the channel layer 132 under the interface between the channel layer 132 and the barrier layer 136. The two-dimensional electron gas 134 may have very high electron mobility.

The gate electrode layer 155 may be located on the barrier layer 136. The gate electrode layer 155 may be overlapped with a portion of the barrier layer 136 in the third direction D3. The gate electrode layer 155 may be overlapped with a portion of the drift region DTR of the channel layer 132 in the third direction D3. The gate electrode layer 155 may be located between the source electrode 173 and the drain electrode 175 in the second direction D2. The gate electrode layer 155 may be spaced apart from the source electrode 173 and the drain electrode 175 in the second direction D2. The gate electrode layer 155 may extend along the first direction D1 on a plane. That is, the gate electrode layer 155 may have a bar shape extending long along the first direction D1 on a plane.

The gate electrode layer 155 may include a conductive material. For example, the gate electrode layer 155 may include a metal, a metal alloy, conductive metal nitride, metal silicide, a doped semiconductor material, conductive metal oxide, or conductive metal oxynitride. For example, the gate electrode layer 155 may be made of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium. (Rh), palladium (Pd), iridium (Ir), osmium (Os), silver (Ag), gold (Au), zinc (Zn), vanadium (V), or a combination thereof, but is not limited thereto. The gate electrode layer 155 may be made of a single layer or multiple layers.

The gate semiconductor layer 152 is located between the barrier layer 136 and the gate electrode layer 155. That is, the gate semiconductor layer 152 may be located on the barrier layer 136, and the gate electrode layer 155 may be located on the gate semiconductor layer 152. The gate electrode layer 155 may be in Schottky contact with the gate semiconductor layer 152. However, it is not limited to this, and in some cases, the gate electrode layer 155 may be in ohmic contact with the gate semiconductor layer 152. The gate semiconductor layer 152 may be overlapped with the gate electrode layer 155 in the third direction D3. The upper surface US_152 of the gate semiconductor layer 152 may be entirely covered by the gate electrode layer 155.

The gate semiconductor layer 152 may be located between the source electrode 173 and the drain electrode 175 in the second direction D2. The gate semiconductor layer 152 may be spaced apart from the source electrode 173 and the drain electrode 175 in the second direction D2. The gate semiconductor layer 152 may be located closer to the source electrode 173 than the drain electrode 175. That is, a separation distance between the gate semiconductor layer 152 and the source electrode 173 may be smaller than a separation distance between the gate semiconductor layer 152 and the drain electrode 175.

The gate semiconductor layer 152 may include nitride including Group III-V materials, for example, Al, Ga, In, B, or a combination thereof. The gate semiconductor layer 152 may include AlₓIn_{y}Ga_{1-x-y}N (0≤x≤1, 0≤y≤1, x+y≤1). For example, the gate semiconductor layer 152 may include AlN, GaN, InN, InGaN, AlGaN, AlInN, AlInGaN, or a combination thereof. The gate semiconductor layer 152 may include a material having an energy bandgap different from that of the barrier layer 136. For example, the gate semiconductor layer 152 may include GaN, and the barrier layer 136 may include AlGaN. The gate semiconductor layer 152 may be doped with a predetermined impurity. At this time, the impurity doped into the gate semiconductor layer 152 may be a p-type dopant that can provide holes. For example, the gate semiconductor layer 152 may include GaN doped with p-type impurities. That is, the gate semiconductor layer 152 may be made of a p-GaN layer. However, it is not limited to this, and the gate semiconductor layer 152 may be a p-AlGaN layer. The impurity doped into the gate semiconductor layer 152 may be magnesium (Mg). The gate semiconductor layer 152 may be made of a single layer or multiple layers.

A depletion region DPR may be formed in the channel layer 132 by the gate semiconductor layer 152. A depletion region DPR may be formed in the channel layer 132 by the gate semiconductor layer 152. The depletion region DPR may be located within the drift region DTR and may have a narrower width than the drift region DTR. As the gate semiconductor layer 152 having a different energy bandgap from the barrier layer 136 is located on the barrier layer 136, a level of the energy band of a portion of the barrier layer 136 that is overlapped with the gate semiconductor layer 152 may increase. Accordingly, the depletion region DPR may be formed in the area of the channel layer 132 that is overlapped with the gate semiconductor layer 152. The depletion region DPR may be a region in the channel path of the channel layer 132 where the two-dimensional electron gas 134 is not formed or may have a lower electron concentration than the remaining regions. That is, the depletion region DPR may refer to a region where the flow of the two-dimensional electron gas 134 is interrupted within the drift region DTR. As the depletion region DPR is generated, current does not flow between the source electrode 173 and the drain electrode 175, and the channel path may be blocked. Accordingly, the semiconductor device may have normally-off characteristics.

That is, the semiconductor device may be a normally-off semiconductor device (HEMT, High Electron Mobility Transistor). In a normal state in which no voltage is applied to the gate electrode layer 155, a depletion region DPR exists and the semiconductor device may be in an off state. Although not shown, when a voltage higher than the threshold voltage is applied to the gate electrode layer 155, the depletion region DPR disappears, and the two-dimensional electron gas 134 may be connected without being disconnected within the drift region DTR. That is, the two-dimensional electron gas 134 may be formed throughout the channel path between the source electrode 173 and the drain electrode 175, and the semiconductor device may be in an on state. In summary, the semiconductor device may include semiconductor layers with different electrical polarization characteristics, and a semiconductor layer with a relatively high polarization rate can induce two-dimensional electron gas 134 in another semiconductor layer that forms heterojunction therewith. This two-dimensional electron gas 134 can be used as a channel between the source electrode 173 and the drain electrode 175, and the continuation or interruption of the flow of the two-dimensional electron gas 134 can be controlled by the bias voltage applied to the gate electrode layer 155. In the gate-off state, the flow of the two-dimensional electron gas 134 is blocked, and thus current may not flow between the source electrode 173 and the drain electrode 175. In the gate-on state, the two-dimensional electron gas 134 continues to flow, and thus current may flow between the source electrode 173 and the drain electrode 175.

Although the case where the semiconductor device is a normally-off high electron mobility transistor has been described above, the present disclosure is not limited thereto. For example, the semiconductor device may be a normally-on high electron mobility transistor. In the case of a normally-on high electron mobility transistor, the gate semiconductor layer 152 may be omitted, and accordingly, the gate electrode layer 155 may be located directly on the barrier layer 136. That is, the gate electrode layer 155 may contact the barrier layer 136. In this structure, the two-dimensional electron gas 134 can be used as a channel while no voltage is applied to the gate electrode layer 155, and current may flow between the source electrode 173 and the drain electrode 175. Additionally, when a negative voltage is applied to the gate electrode layer 155, a depletion region DPR in which the flow of the two-dimensional electron gas 134 is cut off may be generated at the bottom of the gate electrode layer 155.

The buffer layer 120, channel layer 132, barrier layer 136, and gate semiconductor layer 152 described above may be sequentially stacked on the substrate 110. In the semiconductor device, at least one of the buffer layer 120, the channel layer 132, the barrier layer 136, and the gate semiconductor layer 152 may be omitted. The buffer layer 120, channel layer 132, barrier layer 136, and gate semiconductor layer 152 may be made of the same semiconductor material, and considering the role of each layer and the performance required for the semiconductor device, a material composition ratio of each layer may be different.

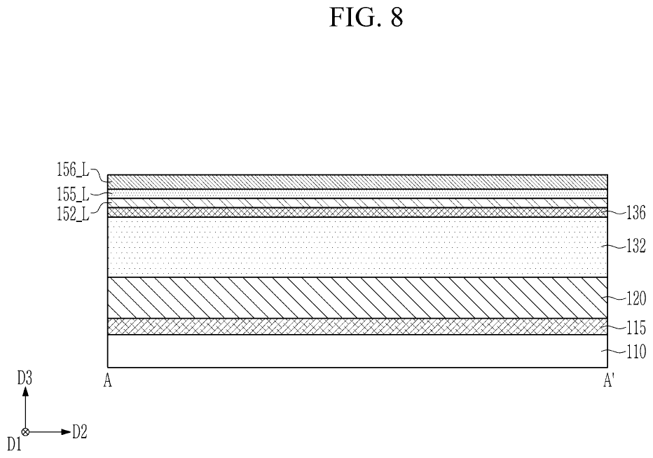

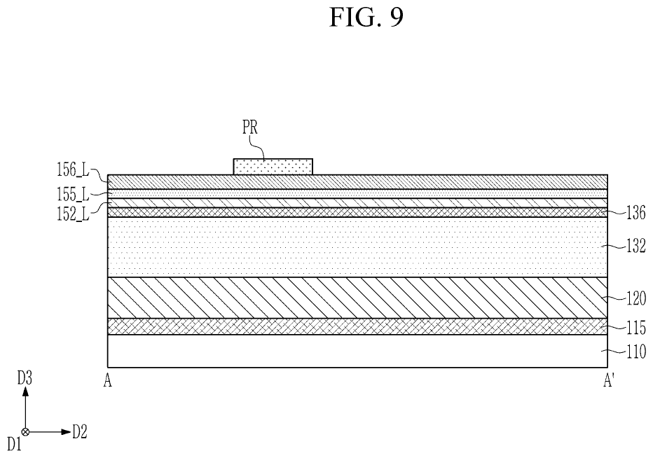

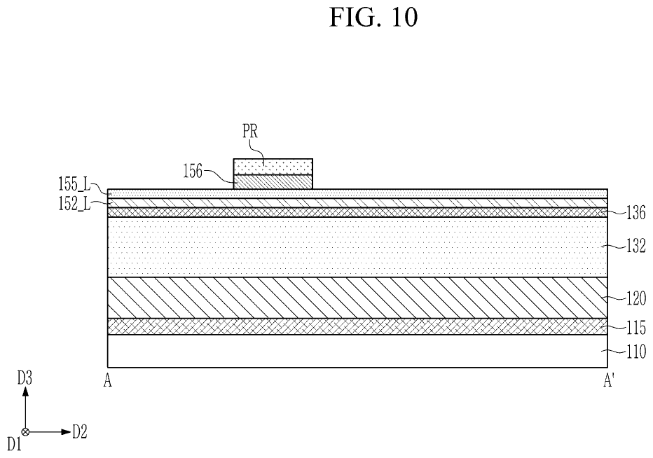

As described later with reference to FIGS. 8 to 14, in the semiconductor device, a gate electrode layer 155 is formed by etching a photoresist pattern (PR in FIG. 9) with a first etching gas, the photoresist pattern PR is removed, and the gate semiconductor layer 152 is formed by etching the hard mask layer (156 in FIG. 10) with a second etching gas different from the first etching gas. That is, as the gate electrode layer 155 is formed using the photoresist pattern PR and the gate semiconductor layer 152 is formed using the hard mask layer 156, the gate electrode layer 155 can be etched with a first etching gas, and the gate semiconductor layer 152 can be etched with a second etching gas, so that a degree of freedom in selecting the etch materials for the gate electrode layer 155 and the gate semiconductor layer 152 increases.

Through this, the side slopes of the gate electrode layer 155 and the gate semiconductor layer 152 can be controlled in various ways, and it is easy to control a field between the side surface SW_152 of the gate semiconductor layer 152 and the upper surface US_136 of the barrier layer 136.

For example, in a cross-sectional view cut in the second direction D2 and the third direction D3 (e.g., FIG. 3), an angle θ_155 formed by the lower surface BS_155 and the side surface SW_155 of the gate electrode layer 155 and an angle θ_152 formed by the lower surface BS_152 and the side surface SW_152 of the gate semiconductor layer 152 may be different from each other. For example, the angle θ_155 formed by the lower surface BS_155 and the side surface SW_155 of the gate electrode layer 155 may be greater than the angle θ_152 formed by the lower surface BS_152 and the side surface SW_152 of the gate semiconductor layer 152.

Herein, the gate electrode layer 155 may have, in a cross-sectional view cut in the second direction D2 and the third direction D3 (e.g., FIG. 3), an upper surface US_155 and a lower surface BS_155 facing each other in the third direction D3 and extending in the second direction D2, respectively, and both side surfaces SW_155 connecting the upper surface US_155 and the lower surface BS_155 and extending in the third direction D3. The upper surface US_155 of the gate electrode layer 155 may face the hard mask layer 156, and the lower surface BS_155 of the gate electrode layer 155 may face the gate semiconductor layer 152. For example, the upper surface US_155 of the gate electrode layer 155 may be defined as a surface in contact with the hard mask layer 156, the lower surface BS_155 of the gate electrode layer 155 may be defined as a surface in contact with the gate semiconductor layer 152, and both side surfaces SW_155 of the gate electrode layer 155 may be defined as surfaces that do not contact the hard mask layer 156 and the gate semiconductor layer 152.

As an example, the angle θ_155 formed between the lower surface BS_155 and the side surface SW_155 of the gate electrode layer 155 may be greater than or equal to about 60°, for example, greater than about 60°, greater than or equal to about 65°, greater than or equal to about 70°, greater than or equal to about 75°, greater than or equal to 80°, or greater than or equal to 85°, and may be less than or equal to about 90°, for example, less than about 90°, less than or equal to about 85°, less than or equal to about 80°, less than or equal to about 75°, less than or equal to about 70°, or less than or equal to 65°, and may be 60° to about 90°.

In addition, the angle θ_152 formed by the lower surface BS_152 and the side surface SW_152 of the gate semiconductor layer 152 may be greater than or equal to about 30°, for example, greater than about 30°, greater than or equal to about 35°, greater than or equal to about 40°, or greater than or equal to about 45°, greater than or equal to about 50°, greater than or equal to about 55°, greater than or equal to about 60°, greater than about 60°, greater than or equal to about 65°, greater than or equal to about 70°, greater than or equal to about 75°, greater than or equal to about 80°, or greater than or equal to about 85°, and may be less than or equal to about 89°, for example, less than about 89°, less than or equal to about 85°, less than or equal to about 80°, less than or equal to about 75°, less than or equal to about 70°, less than or equal to about 65°, less than or equal to about 60°, less than about 60°, less than or equal to about 55°, less than or equal to about 50°, less than or equal to about 45°, less than or equal to about 40°, or less than or equal to about 35° and may be about 30° to about 89°.

Accordingly, in a cross-sectional view cut in the second direction D2 and the third direction D3 (e.g., FIG. 3), a length W_US_155 of the upper surface US_155 of the gate electrode layer 155 in the second direction D2 may be smaller than a length W BS_155 of the lower surface BS_155 of the gate electrode layer 155 in the second direction D2. In addition, a length W_US_152 of the upper surface US_152 of the gate semiconductor layer 152 in the second direction D2 may be smaller than a length W_BS_152 of the lower surface BS_152 of the gate semiconductor layer 152 in the second direction D2. In addition, a difference (=W_BS_155−W_US_155) in a length between the lower surface BS_155 and the upper surface US_155 of the gate electrode layer 155 in the second direction D2 may be smaller than a difference (=W_BS_152−W_US_152) in a length between the lower surface BS_152 and the upper surface US_152 of the gate semiconductor layer 152 in the second direction D2.

As described above, by-products generated when the gate electrode layer 155 is etched with the first etching gas may affect and cause defects when the gate semiconductor layer 152 is etched with the second etching gas. In order to solve this problem, after etching the gate electrode layer 155 with a first etching gas, before etching the gate semiconductor layer 152 with a second etching gas, by-products generated when the gate electrode layer 155 is etched with the first etching gas can be removed through a process such as ashing or stripping. Accordingly, the problem of defects caused by by-products caused by etching the dissimilar materials of the gate electrode layer 155 and the gate semiconductor layer 152 with different etching materials can be solved.

In the process of removing by-products through processes such as ashing or stripping, the photoresist pattern PR may also be removed. During this process, the hard mask layer 156 is not removed. The hard mask layer 156 may be used as a mask in a subsequent process of forming the gate semiconductor layer 152 using a second etching gas. When the gate semiconductor layer 152 is etched, the hard mask layer 156 is partially etched according to the etching conditions, and the hard mask layer 156 may have a shape in which the edge formed by the upper surface US_156 and the side surface SW_156 may be rounded. As the edge of the hard mask layer 156 have a round shape, the angle θ_177a formed by the lower surface BS_177a1 of the landing portion 177a1 of the first field dispersion layer 177a, which will be described later, and the lower surface BS_177a3 of the connection portion 177a3 can be adjusted, so that it is possible to prevent voids from forming during formation of the first field dispersion layer 177a.

Accordingly, the semiconductor device may further include a hard mask layer 156 on the gate electrode layer 155. However, the hard mask layer 156 may be removed depending on the etching conditions when the gate semiconductor layer 152 is etched.

If the hard mask layer 156 includes the same material as the first protective layer 140, which will be described later, the boundary between the hard mask layer 156 and the first protective layer 140 may not be distinguished. In this case, because the distance in the third direction D3 from the upper surface US_155 of the gate electrode layer 155 to the lower surface of the overlapping portion 177a2 of the first field dispersion layer 177a includes the distance of the first protective layer 140 in the third direction D3 and the distance of the hard mask layer 156 in the third direction D3, the distance from the upper surface US_155 of the gate electrode layer 155 to the lower surface of the overlapping portion 177a2 of the first field dispersion layer 177a in the third direction D3 may be greater than the distance in the third direction D3 from the upper surface US_136 of the barrier layer 136 to the lower surface of the landing portion 177a1 of the first field dispersion layer 177a.

In a cross-sectional view cut in the second direction D2 and the third direction D3 (e.g., FIG. 3), the hard mask layer 156 may have an upper surface US_156 and a lower surface BS_156 that face each other in the third direction D3 and extend in the second direction D2, and both side surfaces SW_156 connecting the upper surface US_156 and the lower surface BS_156 and extending in the third direction D3. The upper surface US_156 of the hard mask layer 156 may face the overlapping portion 177a2 of the first protective layer 140 and the first field dispersion layer 177a, and the lower surface BS_156 of the hard mask layer 156 may face the gate electrode layer 155.

The upper surface US_156 of the hard mask layer 156 may extend from the midpoint of the hard mask layer 156 in the second direction D2 to both ends of the second direction D2. The upper surface US_156 of the hard mask layer 156 may have different heights in the second direction D2. For example, the height at both ends of the upper surface US_156 of the hard mask layer 156 in the second direction D2 may be within ±30%, within ±20%, within ±10%, within ±5%, or within ±1% relative to the height at the midpoint of the second direction D2, and the point where the height exceeds ±30%, ±20%, ±10%, ±5%, or ±1% relative to the height at the midpoint of the second direction D2 may correspond to the side surface SW_156 of the hard mask layer 156.

The lower surface BS_156 of the hard mask layer 156 may extend from the midpoint of the second direction D2 to both ends of the second direction D2. The lower surface BS_156 of the hard mask layer 156 may have different heights in the second direction D2. For example, the height at both ends of the upper surface BS_156 of the hard mask layer 156 in the second direction D2 may be within ±30%, within ±20%, within ±10%, within ±5%, or within ±1% relative to the height at the midpoint of the second direction D2, and the point where the height exceeds ±30%, ±20%, ±10%, ±5%, or ±1% relative to the height at the midpoint of the second direction D2 may correspond to the side surface SW_156 of the hard mask layer 156.

In a cross-sectional view cut in the second direction D2 and the third direction D3 (e.g., FIG. 3), the edge formed by the upper surface US_156 and the side surface SW_156 of the hard mask layer 156 may have a round shape. In other words, the edge formed by the upper surface US_156 and the side surface SW_156 of the hard mask layer 156 may not have an angular shape but may have an obliquely rounded shape, and for example, may have a curvature.

Accordingly, the angle θ_156U formed between the upper surface US_156 and the side surface SW_156 of the hard mask layer 156 may become smaller as the distance from the upper surface US_156 of the hard mask layer 156 in the third direction D3 increases. Herein, an angle θ_156U formed between the upper surface US_156 and the side surface SW_156 of the hard mask layer 156 in the third direction D3 may be an interior angle of the tangent at a point on the side surface SW_156 and the upper surface US_156.

In addition, a ratio of the length W_US_156 of the upper surface US_156 of the hard mask layer 156 in the second direction D2 and the length W_BS_156 of the lower surface BS_156 of the hard mask layer 156 in the second direction D2 may be about 9:10 or more, for example about 9:10.5 or more, about 9:11 or more, or about 9:11.5 or more, and may be about 9:12 or less, for example about 9:11.5 or less, about 9:11 or less, or about 9:10.5 or less, and may be about 9:10 to about 9:12. The length W_US_156 of the upper surface US_156 of the hard mask layer 156 in the second direction D2 may be the length measured by a substantially flat upper surface US_156 in the second direction D2 except for the rounded shape of the edge. Herein, flat may mean parallel to the second direction D2.

For example, in a cross-sectional view cut in the second direction D2 and the third direction D3 (e.g., FIG. 3), the angle θ_155 formed by the lower surface BS_155 and the side surface SW_155 of the gate electrode layer 155 and the angle θ_156U formed by the upper surface US_156 and the side surface SW_156 of the hard mask layer 156 may be different from each other. For example, the angle θ_156U formed by the upper surface US_156 and the side surface SW_156 of the hard mask layer 156 may be greater than the angle θ_155 formed by the lower surface BS_155 and the side surface SW_155 of the gate electrode layer 155.

As an example, the angle θ_156U formed between the upper surface US_156 and the side surface SW_156 of the hard mask layer 156 may be greater than or equal to about 90°, for example, greater than about 90°, greater than or equal to about 95°, greater than or equal to about 100°, greater than or equal to about 105°, greater than or equal to 110°, or greater than or equal to 115°, and may be less than or equal to about 120°, for example less than about 120°, less than or equal to about 115°, less than or equal to about 110°, less than or equal to about 105°, or less than or equal to about 100°, or less than or equal to about 95°, or less than or equal to about 90°, and may be about 90° to about 120°.

As an example, the hard mask layer 156 may include silicon oxide, silicon nitride, silicon nitride, or a combination thereof.

The semiconductor device may further include first to third protective layers 140, 150, and 160 on the barrier layer 136, the gate electrode layer 155, and the hard mask layer 156. As an example, the semiconductor device may include a first protective layer 140, a second protective layer 150 on the first protective layer 140, and a third protective layer 160 on the second protective layer 150. The first protective layer 140 may cover the barrier layer 136, the gate electrode layer 155, and the upper surface US_155 of the hard mask layer 156, and may cover the side surface SW_155 of the gate electrode layer 155, the side surface SW_152 of the gate semiconductor layer 152, and the side surface SW_156 of the hard mask layer 156. The lower surface of the first protective layer 140 may be in contact with the barrier layer 136, the gate electrode layer 155, the gate semiconductor layer 152, and the hard mask layer 156. The upper surface of the first protective layer 140 may be in contact with the second protective layer 150. The second and third protective layers 150 and 160 may be spaced apart from the barrier layer 136, the gate electrode layer 155, the gate semiconductor layer 152, and the hard mask layer 156 by the first protective layer 140. Accordingly, the second and third protective layers 150 and 160 may not contact the barrier layer 136, the gate electrode layer 155, the gate semiconductor layer 152, and the hard mask layer 156.

The barrier layer 136 or the gate electrode layer 155 may be protected by the first to third protective layers 140, 150, and 160 and may be separated from other components. The first to third protective layers 140, 150, and 160 may include an insulating material. For example, the first to third protective layers 140, 150, and 160 may include an oxide such as SiO₂ or Al₂O₃. As another example, the first to third protective layers 140, 150, and 160 may include nitride such as SiN or oxynitride such as SiON. The first to third protective layers 140, 150, and 160 may include the same material or different materials. If the first to third protective layers 140, 150, and 160 are made of the same material, boundaries between the first to third protective layers 140, 150, and 160 may not be visible. The first to third protective layers 140, 150, and 160 may each be made of a single layer or multiple layers.

The source electrode 173 and the drain electrode 175 may be located on the channel layer 132. The source electrode 173 and the drain electrode 175 may be spaced apart from each other in the second direction D2, and the hard mask layer 156, the gate electrode layer 155, and the gate semiconductor layer 152 may be located between the source electrode 173 and the drain electrode 175. The hard mask layer 156, the gate electrode layer 155, and the gate semiconductor layer 152 may be spaced apart from the source electrode 173 and the drain electrode 175 in the second direction D2. The source electrode 173 may be electrically connected to the channel layer 132 on one side of the gate electrode layer 155 in the second direction D2. The drain electrode 175 may be electrically connected to the channel layer 132 on the other side of the gate electrode layer 155 in the second direction D2. The source electrode 173 and the drain electrode 175 may be located outside the drift region DTR of the channel layer 132. The boundary between the source electrode 173 and the channel layer 132 may be one edge of the drift region DTR. Likewise, the boundary between the drain electrode 175 and the channel layer 132 may be the other edge of the drift region DTR. However, the present disclosure is not limited thereto, and the source electrode 173 and the drain electrode 175 may not be located outside the drift region DTR of the channel layer 132. At this time, the channel layer 132 may not be recessed, and the source electrode 173 and the drain electrode 175 may be located on the upper surface of the channel layer 132. The lower surfaces of the source electrode 173 and the drain electrode 175 may contact the upper surface of the channel layer 132. A portion of the channel layer 132 in contact with the source electrode 173 and the drain electrode 175 may be doped at a high concentration. At this time, the carriers passing through the two-dimensional electron gas 134 may pass through the highly doped channel layer 132, that is, may be transmitted to the source electrode 173 and the drain electrode 175 through the upper of the two-dimensional electron gas 134. The source electrode 173 and the drain electrode 175 may not directly contact the two-dimensional electron gas 134 in the horizontal direction. The horizontal direction may refer to a direction parallel to the upper surface US_136 of the channel layer 132 or the barrier layer 136.

The source electrode 173 and the drain electrode 175 may extend along the first direction D2 on a plane. That is, the source electrode 173 and the drain electrode 175 may have a rod shape extending long along the first direction D1 on a plane. The source electrode 173 and the drain electrode 175 may extend in parallel directions. The source electrode 173 and the drain electrode 175 may extend in a direction parallel to the gate electrode layer 155.

The source electrode 173 and the drain electrode 175 may include a conductive material. For example, the source electrode 173 and the drain electrode 175 may include a metal, a metal alloy, conductive metal nitride, metal silicide, a doped semiconductor material, conductive metal oxide, or conductive metal oxynitride. For example, the source electrode 173 and the drain electrode 175 may be made of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium. (Rh), palladium (Pd), iridium (Ir), osmium (Os), silver (Ag), gold (Au), zinc (Zn), vanadium (V), or a combination thereof, but are not limited thereto. The source electrode 173 and the drain electrode 175 may be made of a single layer or multiple layers. The source electrode 173 and the drain electrode 175 may be in ohmic contact with the channel layer 132. A region in contact with the source electrode 173 and the drain electrode 175 within the channel layer 132 may be doped at a relatively high concentration compared to other regions.

The source electrode 173 may include the lower source electrode 173a, the middle source electrode 173b, and the upper source electrode 173c. The middle source electrode 173b may be located on the lower source electrode 173a. The upper source electrode 173c may be located on the middle source electrode 173b. The lower source electrode 173a may be in direct contact with the channel layer 132 and may be electrically connected to the channel layer 132. The middle source electrode 173b and the upper source electrode 173c may not be in direct contact with the channel layer 132, and may be electrically connected to the channel layer 132 through the lower source electrode 173a.

The drain electrode 175 may include the lower drain electrode 175a, the middle drain electrode 175b, and the upper drain electrode 175c. The middle drain electrode 175b may be located on the lower drain electrode 175a. The upper drain electrode 175c may be located on the middle drain electrode 175b. The lower drain electrode 175a may be in direct contact with the channel layer 132 and may be electrically connected to the channel layer 132. The middle drain electrode 175b and the upper drain electrode 175c may not be in direct contact with the channel layer 132, and may be electrically connected to the channel layer 132 through the lower drain electrode 175a.

The upper surfaces of the lower source electrode 173a and the lower drain electrode 175a may be located on the first protective layer 140. The upper surfaces of the lower source electrode 173a and the lower drain electrode 175a may be located between the first protective layer 140 and the second protective layer 160. The lower source electrode 173a and the lower drain electrode 175a penetrate the first protective layer 140 and the barrier layer 136, and the trenches recessing the upper surface of the channel layer 132 may be located on both sides of the gate electrode layer 155 to be spaced apart from each other. The lower source electrode 173a and the lower drain electrode 175a may be located in the trench on both sides of the gate electrode layer 155, respectively. The lower source electrode 173a and the lower drain electrode 175a may be formed to fill the trench. Within the trench, the lower source electrode 173a and the lower drain electrode 175a may contact the channel layer 132 and the barrier layer 136. The channel layer 132 may form the bottom and side walls of the trench, and the barrier layer 136 may form the side walls of the trench. Accordingly, the lower source electrode 173a and the lower drain electrode 175a may contact the upper surface and side surfaces of the channel layer 132. Additionally, the lower source electrode 173a and the lower drain electrode 175a may contact the side surface of the barrier layer 136. That is, the lower source electrode 173a and the lower drain electrode 175a may cover the side surfaces of the channel layer 132 and the barrier layer 136. The upper surfaces of the lower source electrode 173a and the lower drain electrode 175a may protrude from the upper surface of the first protective layer 140. Additionally, at least one of the lower source electrode 173a and the lower drain electrode 175a may cover at least a portion of the upper surface of the first protective layer 140. A second protective layer 160 may be located on the lower source electrode 173a and the lower drain electrode 175a. At least a portion of the lower source electrode 173a and the lower drain electrode 175a may be covered by the second protective layer 160.

The semiconductor device may further include a first field dispersion layer 177a on the first protective layer 140. The first field dispersion layer 177a may be located between the source electrode 173 and the drain electrode 175. The gate electrode layer 155 may be covered by the first field dispersion layer 177a. The first field dispersion layer 177a may be electrically connected to the source electrode 173. For example, the first field dispersion layer 177a may be connected to the lower source electrode 173a. The first field dispersion layer 177a may include the same material as the lower source electrode 173a and may be located in the same layer as the lower source electrode 173a. The first field dispersion layer 177a may be formed simultaneously with the lower source electrode 173a in the same process. The boundary between the first field dispersion layer 177a and the lower source electrode 173a is not clear, and the first field dispersion layer 177a may be formed integrally with the lower source electrode 173a. However, the present disclosure is not limited thereto, and the first field dispersion layer 177a may be a separate element from the lower source electrode 173a. Additionally, the first field dispersion layer 177a may be located in a different layer from the lower source electrode 173a and may be formed in a different process. In some cases, the first field dispersion layer 177a may be electrically connected to the gate electrode layer 155. For example, an opening that is overlapped with the gate electrode layer 155 may be formed in the first protective layer 140, and the first field dispersion layer 177a may be connected to the gate electrode layer 155 through the opening. At this time, the first field dispersion layer 177a may not be connected to the source electrode 173.

The first field dispersion layer 177a may be overlapped with the gate electrode layer 155 in the third direction D3. For example, the first field dispersion layer 177a may include an overlapping portion 177a2 overlapped with the gate electrode layer 155 in the third direction D3, a landing portion 177a1 on both sides of the overlapping portion 177a2 in the second direction D2, and a connection portion 177a3 connecting the overlapping portion 177a2 and the landing portion 177a1.

The landing portion 177a1 may not be overlapped with the gate electrode layer 155 in the third direction D3. The landing portion 177a1 may have a closer distance from the upper surface US_136 of the barrier layer 136 in the third direction D3 (hereinafter referred to as “height in the third direction D3”) than the overlapping portion 177a2. In other words, as the gate electrode layer 155 is located under the overlapping portion 177a2, and the gate electrode layer 155 is not located under the landing portion 177a1 and the thickness of the first protective layer 140 located between the gate electrode layer 155 and the first field dispersion layer 177a in the second direction D2 and the thickness of the first protective layer 140 located between the barrier layer 136 and the first field dispersion layer 177a in the second direction D2 are constant, a height of the overlapping portion 177a2 located on the gate electrode layer 155 in the third direction D3 may be higher than a height of the landing portion 177a1 in the third direction D3.

The connection portion 177a3 connects the overlapping portion 177a2 and the landing portion 177a1 with different heights in the third direction D3, and thus the height in the third direction D3 may increase as it moves from the landing portion 177a1 to the overlapping portion 177a2 in the second direction D2.

As described above, when the gate semiconductor layer 152 is etched, while partially etching the hard mask layer 156 according to the etching conditions and the hard mask layer 156 may have a shape in which the edge formed by the upper surface US_156 and the side surface SW_156 are rounded. As the edge of the hard mask layer 156 have a rounded shape, the angle θ_177a formed by the lower surface BS_177a1 of the landing portion 177a1 of the first field dispersion layer 177a and the lower surface BS_177a3 of the connection portion 177a3 can be adjusted, and thus the generation of voids can be prevented when forming the first field dispersion layer 177a.

For example, in a cross-sectional view cut in the second direction D2 and the third direction D3 (e.g., FIG. 3), the angle θ_177a formed by the lower surface BS_177a1 of the landing portion 177a1 of the first field dispersion layer 177a and the lower surface BS_177a3 of the connecting portion 177a3 may be greater than or equal to about 90°, for example, greater than about 90°, greater than or equal to about 100°, greater than or equal to about 110°, greater than or equal to about 120°, greater than or equal to about 130°, or greater than or equal to about 140° and less than or equal to about 150°, for example less than about 150°, less than or equal to about 140°, less than or equal to about 130°, less than or equal to about 120°, less than or equal to about 110°, or less than or equal to about 100°, and may be about 90° to about 150°.

The semiconductor device may further include a second field dispersion layer 177b located on the second protective layer 150. The second field dispersion layer 177b may form a field dispersion layer together with the first field dispersion layer 177a. The second field dispersion layer 177b may be located between the source electrode 173 and the drain electrode 175. The second field dispersion layer 177b may be overlapped with the gate electrode layer 155 in the third direction D3. The second field dispersion layer 177b may be overlapped with the first field dispersion layer 177a in the third direction D3. The gate electrode layer 155 and the first field dispersion layer 177a may be covered by the second field dispersion layer 177b. The second field dispersion layer 177b may be wider than the first field dispersion layer 177a. The second field dispersion layer 177b may entirely cover the first field dispersion layer 177a. However, the present disclosure is not limited thereto, and the width and positional relationship of the first field dispersion layer 177a and the second field dispersion layer 177b may be changed in various ways. The second field dispersion layer 177b may be electrically connected to the source electrode 173. For example, the second field dispersion layer 177b may be connected to the middle source electrode 173b. The second field dispersion layer 177b may include the same material as the middle source electrode 173b and may be located in the same layer as the middle source electrode 173b. The second field dispersion layer 177b may be formed simultaneously with the middle source electrode 173b in the same process. The boundary between the second field dispersion layer 177b and the middle source electrode 173b is not clear, and the second field dispersion layer 177b may be formed integrally with the middle source electrode 173b. However, the present disclosure is not limited thereto, and the second field dispersion layer 177b may be a separate component separated from the middle source electrode 173b. Additionally, the second field dispersion layer 177b may be located in a different layer from the middle source electrode 173b and may be formed in a different process.

The semiconductor device may further include a third field dispersion layer 177c on the third protective layer 160. The third field dispersion layer 177c may form a field dispersion layer together with the first field dispersion layer 177a and the second field dispersion layer 177b. The third field dispersion layer 177c may be located between the source electrode 173 and the drain electrode 175. The third field dispersion layer 177c may be overlapped with the gate electrode layer 155 in the third direction D3. The third field dispersion layer 177c may be overlapped with the first field dispersion layer 177a and the second field dispersion layer 177b in the third direction D3. The gate electrode layer 155, the first field dispersion layer 177a, and the second field dispersion layer 177b may be covered by the third field dispersion layer 177c. The third field dispersion layer 177c may have a larger width than the second field dispersion layer 177b. The third field dispersion layer 177c may entirely cover the second field dispersion layer 177b. However, the present disclosure is not limited thereto, and the width and positional relationship of the first field dispersion layer 177a, the second field dispersion layer 177b, and the third field dispersion layer 177c may be changed in various ways. The third field dispersion layer 177c may be electrically connected to the source electrode 173. For example, the third field dispersion layer 177c may be connected to the upper source electrode 173c. The third field dispersion layer 177c may include the same material as the upper source electrode 173c and may be located in the same layer as the upper source electrode 173c. The third field dispersion layer 177c may be formed simultaneously in the same process as the upper source electrode 173c. The boundary between the third field dispersion layer 177c and the upper source electrode 173c is not clear, and the third field dispersion layer 177c may be formed integrally with the upper source electrode 173c. However, the present disclosure is not limited thereto, and the third field dispersion layer 177c may be a separate element separated from the upper source electrode 173c. Additionally, the third field dispersion layer 177c may be located in a different layer from the upper source electrode 173c and may be formed in a different process.

In some implementations, at least one of the first field dispersion layer 177a, the second field dispersion layer 177b, or the third field dispersion layer 177c may be omitted. For example, the semiconductor device may include the first field dispersion layer 177a and may not include the second field dispersion layer 177b or the third field dispersion layer 177c. Alternatively, the semiconductor device may include the second field dispersion layer 177b and not include the first field dispersion layer 177a or the third field dispersion layer 177c. Alternatively, the semiconductor device may include the third field dispersion layer 177c and not include the first field dispersion layer 177a or the second field dispersion layer 177b. Alternatively, the semiconductor device may not include the first field dispersion layer 177a, the second field dispersion layer 177b, and the third field dispersion layer 177c.

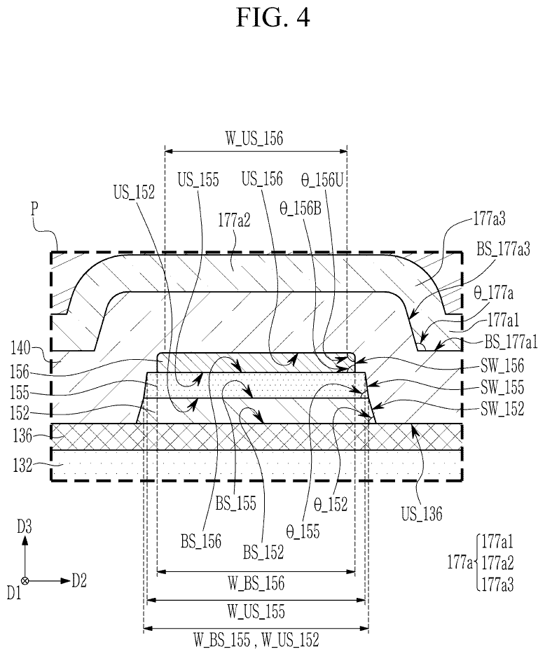

FIG. 4 is an example enlarged cross-sectional view of portion P of FIG. 2.

Since the implementation shown in FIG. 4 has many of the same parts as the implementation shown in FIG. 3, the description thereof will be omitted and the differences will be mainly explained. Additionally, the same reference numerals are used for the same components as those in the previous implementation.

Referring to FIG. 4, the length W_BS_156 of the hard mask layer 156 in the second direction D2 of the lower surface BS_156 may be reduced depending on the etching conditions when etching the gate semiconductor layer 152.

Accordingly, in the cross-sectional view cut in the second direction D2 and the third direction D3 (e.g., FIG. 4), the length W_BS_156 of the lower surface BS_156 of the hard mask layer 156 in the second direction D2 may be smaller than the length W_US_155 of the upper surface of the gate electrode layer 155 in the second direction D2.

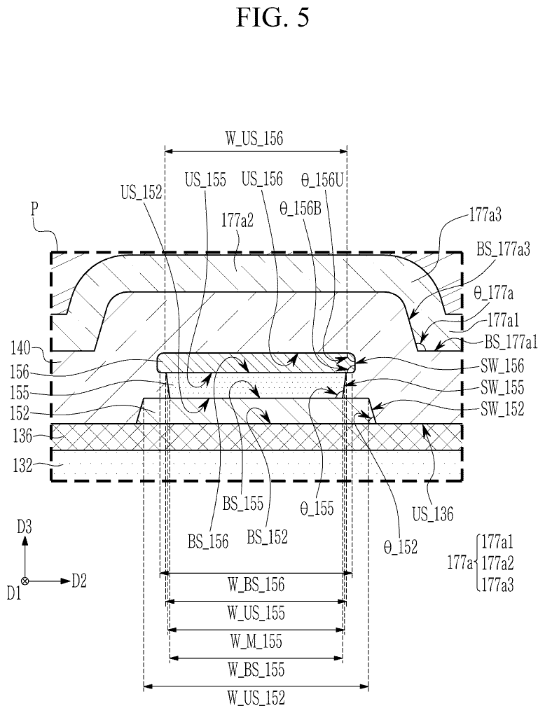

FIG. 5 is an example enlarged cross-sectional view of portion P of FIG. 2.

Since the implementation shown in FIG. 5 has many of the same parts as the implementation shown in FIG. 3, description thereof will be omitted and the differences will be mainly explained. Additionally, the same reference numerals are used for the same components as those in the previous implementation.

Referring to FIG. 5, the length W_US_155 of the upper surface US_155 in the second direction D2 and the length W_BS_155 of the lower surface BS_155 in the second direction D2 may be reduced depending on the etching conditions when etching the gate semiconductor layer 152.

In a cross-sectional view cut in the second direction D2 and the third direction D3 (e.g., FIG. 5), the length W_US_155 of the upper surface US_155 of the gate electrode layer 155 in the second direction D2 and the length W_BS_155 of the lower surface BS_155 in the second direction D2 may be smaller than the length W_BS_156 of the lower surface BS_156 of the hard mask layer 156 in the second direction D2 and the length W_US_152 of the upper surface US_152 of the gate semiconductor layer 152 in the second direction D2.

In addition, the length W_BS_155 of the lower surface BS_155 of the gate electrode layer 155 in the second direction D2 may be smaller than the length W_US_155 of the upper surface US_155 of the gate electrode layer 155 in the second direction D2. Accordingly, in a cross-sectional view cut in the second direction D2 and the third direction D3 (e.g., FIG. 3), the gate electrode layer 155 may have an inverted trapezoidal shape.

As described above, the hard mask layer 156 is partially etched according to the etching conditions when etching the gate semiconductor layer 152, and in the hard mask layer 156, the edge formed by the upper surface US_156 and the side surface SW_156 as well as the edge formed by the lower surface BS_156 and the side surface SW_156 may have a rounded shape.

In a cross-sectional view cut in the second direction D2 and the third direction D3 (e.g., FIG. 5), the edge formed by the lower surface BS_156 and the side surface SW_156 of the hard mask layer 156 may have a rounded shape. In other words, the edge formed by the lower surface BS_156 and the side surface SW_156 of the hard mask layer 156 may not have an angular shape but may have an obliquely cut round shape, for example, may have a curvature.

The angle θ_156B formed between the lower surface BS_156 and the side surface SW_156 of the hard mask layer 156 may become smaller as the distance from the lower surface BS_156 of the hard mask layer 156 in the third direction (D3) increases. Herein, the angle θ_156B formed between the lower surface BS_156 and the side surface SW_156 of the hard mask layer 156 in the third direction D3 may be an interior angle of the tangent at a point on the side surface SW_156 and the lower surface BS_156.

As an example, the angle θ_156B formed by the lower surface BS_156 and the side surface SW_156 of the hard mask layer 156 may be greater than or equal to about 90°, for example, greater than about 90°, greater than or equal to about 95°, greater than or equal to about 100°, greater than or equal to about 105°, greater than or equal to 110°, or greater than or equal to 115°, and may be less than or equal to about 120°, for example less than about 120°, less than or equal to about 115°, less than or equal to about 110°, less than or equal to about 105°, or less than or equal to about 100°, or less than or equal to about 95°, or less than or equal to about 90°, and may be about 90° to about 120°.

The rounded shape of the edge formed by the upper surface US_156 and the side surface SW_156 of the hard mask layer 156 may be gentler than the rounded shape of the edge formed by the lower surface BS_156 and the side surface SW_156 of the hard mask layer 156 and the rounded shape of the edge formed by the bottom surface BS_156 and the side surface SW_156 of the hard mask layer 156 may be steeper than the rounded shape of the edge formed by the upper surface US_156 and the side surface SW_156 of the hard mask layer 156. In other words, the curvature of the edge formed by the upper surface US_156 and the side surface SW_156 of the hard mask layer 156 may be smaller than the curvature of the edge formed by the lower surface BS_156 and the side surface SW_156 of the hard mask layer 156.

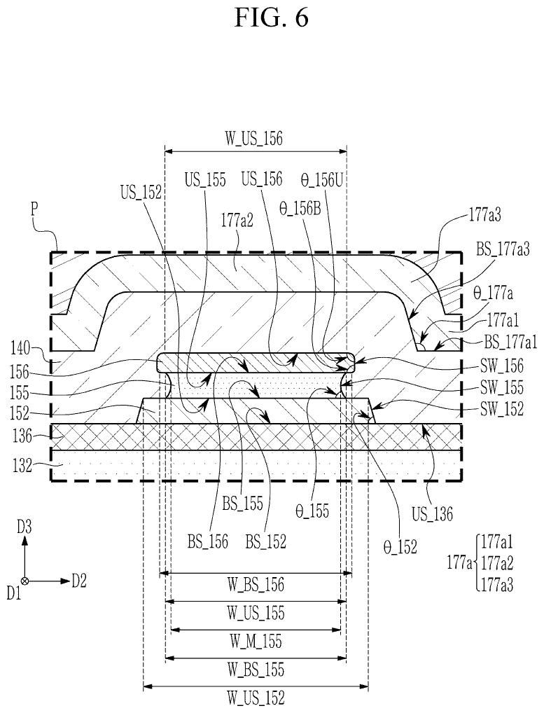

FIG. 6 is an example enlarged cross-sectional view of portion P of FIG. 2.

Since the implementation shown in FIG. 6 has many of the same parts as the implementation shown in FIG. 5, description thereof will be omitted and the differences will be mainly explained. Additionally, the same reference numerals are used for the same components as those in the previous implementation.

In FIG. 5, the length W_BS_155 of the lower surface BS_155 in the second direction D2 is reduced more than the length W_US_155 of the upper surface US_155 in the second direction D2, according to the etching conditions when the gate semiconductor layer 152 is etched. It is further reduced than the length W_US_155 in D2, and in a cross-sectional view cut in the second direction D2 and the third direction D3 (e.g., FIG. 5), the gate electrode layer 155 is shown to have an inverted trapezoidal shape. In this case, the length W_M_155 from the midpoint in the third direction (D3) between the upper surface US_155 and the lower surface BS_155 of the gate electrode layer 155 in the second direction D2 may be smaller than the length W_US_155 of the upper surface US_155 of the gate electrode layer 155 in the second direction D2 and may be larger than the length W_BS_155 of the lower surface BS_155 in the second direction D2.

Referring to FIG. 6, when the gate electrode layer 155 is etched, depending on the etching conditions, both side surfaces SW_155 of the gate electrode layer 155 have a concave shape toward the gate electrode layer 155.

Accordingly, the length W_M_155 from the midpoint in the third direction D3 between the upper surface US_155 and the lower surface BS_155 of the gate electrode layer 155 in the second direction D2 may be smaller than the length W_US_155 of the upper surface US_155 of the gate electrode layer 155 in the second direction D2 and the length W_BS_155 of the lower surface BS_155 in the second direction D2.

For example, the length of the gate electrode layer 155 in the second direction (D2) may approximately decrease from the upper surface (US_155) of the gate electrode layer 155 to the midpoint of the third direction (D3) in the third direction (D3) and then after having a minimum value near the midpoint of the third direction D3, it may approximately increase from the midpoint of the third direction D3 to the lower surface BS_155.

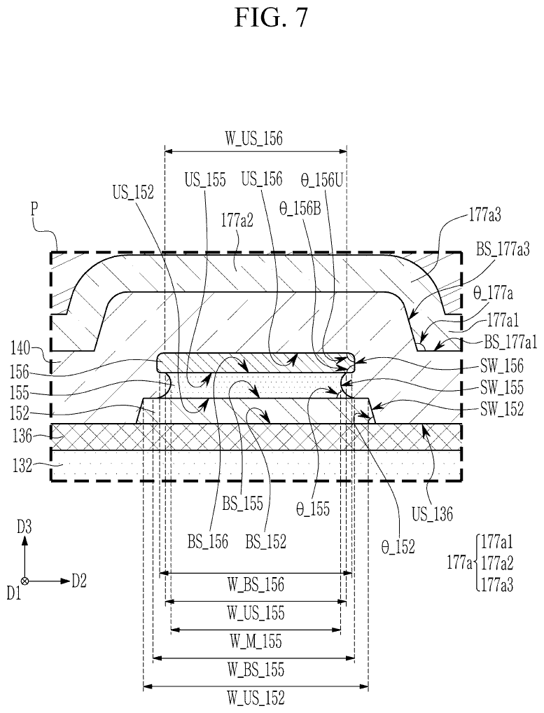

FIG. 7 is an example enlarged cross-sectional view of portion P of FIG. 2.

Since the implementation shown in FIG. 7 has many of the same parts as the implementation shown in FIG. 6, description thereof will be omitted and the differences will be mainly explained. Additionally, the same reference numerals are used for the same components as those in the previous implementation.

In FIG. 6, the length W_M_155 from the midpoint in the third direction D3 between the upper surface US_155 and the lower surface BS_155 of the gate electrode layer 155 in the second direction D2 may be smaller than the length W_US_155 of the upper surface US_155 of the gate electrode layer 155 in the second direction D2 and the length W_BS_155 of the lower surface BS_155 in the second direction D2, but the length W_US_155 of the upper surface US_155 of the gate electrode layer 155 in the second direction D2 and the length W_BS_155 of the lower surface BS_155 in the second direction D2 are shown to be approximately similar.

Referring to FIG. 7, the length W_M_155 from the midpoint in the third direction D3 between the upper surface US_155 and the lower surface BS_155 of the gate electrode layer 155 in the second direction D2 may be smaller than the length W_US_155 of the upper surface US_155 of the gate electrode layer 155 in the second direction D2 and the length W_BS_155 of the lower surface BS_155 of the gate electrode layer 155 in the second direction D2. The length W_US_155 of the upper surface US_155 of the gate electrode layer 155 in the second direction D2 may be smaller than the length W_BS_155 of the lower surface BS_155 of the gate electrode layer 155 in the second direction D2. FIG. 7 shows that the length W_BS_155 of the lower surface BS_155 of the gate electrode layer 155 in the second direction D2 is larger than the length W_US_156 of the upper surface US_156 and the length W_BS_156 of the lower surface BS_156 of the hard mask layer 156, but this is illustrative. As another example, in the second direction D2, the length W_BS_155 of the lower surface BS_155 of the gate electrode layer 155 may be smaller than the length W_US_156 of the upper surface US_156 and the length W_BS_156 of the lower surface BS_156 of the hard mask layer 156.

Next, a method of manufacturing a semiconductor device according to an implementation will be described with reference to FIGS. 8 to 14. In addition, FIGS. 1 to 3 described above may also be referred to.

FIGS. 8, 9, 10, 11, 12, 13, and 14 are cross-sectional views showing an example of a semiconductor device manufacturing method according to process sequence.

Referring to FIG. 8, a seed layer 115, a buffer layer 120, a channel layer 132, and a barrier layer 136 may be sequentially formed on the substrate 110. Additionally, a gate semiconductor material layer 152_L, a gate electrode material layer 155_L, and a hard mask material layer 156_L may be sequentially formed on the barrier layer 136.

The seed layer 115, buffer layer 120, channel layer 132, barrier layer 136, and gate semiconductor material layer 152_L may be sequentially formed using an epitaxial growth method. The seed layer 115 may be formed on the substrate 110 first, and the buffer layer 120 may be formed on the seed layer 115. The buffer layer 120 may include a superlattice layer and a high-resistance layer. A channel layer 132 may be formed on the buffer layer 120, a barrier layer 136 may be formed on the channel layer 132, and a gate semiconductor material layer 152_L may be formed on the barrier layer 136.

The seed layer 115, buffer layer 120, channel layer 132, barrier layer 136, and gate semiconductor material layer 152_L may be made of the same semiconductor material. However, considering the role of each layer and the performance required for the semiconductor device, the material composition ratio of each layer may be different.

For example, the substrate 110 includes Si, the seed layer 115 includes AlN, and the superlattice layer of the buffer layer 120 has a structure in which a layer made of AlGaN and a layer made of GaN are repeatedly stacked. The high-resistance layer of the buffer layer 120 may include GaN, the channel layer 132 may include GaN, and the barrier layer 136 may include AlGaN. The channel layer 132 and the barrier layer 136 may or may not be doped with impurities. The gate semiconductor material layer 152_L may include GaN and may be doped with impurities. The gate semiconductor material layer 152_L may be doped with a p-type impurity, for example, magnesium (Mg).

As the lattice structure of Si and GaN are different, it may not be easy to grow the channel layer 132 made of GaN directly on the substrate 110 made of Si. Accordingly, by first forming the seed layer 115 or the buffer layer 120 on the substrate 110 and then forming the channel layer 132, the lattice structure of the channel layer 132 can be stably formed.

A gate electrode material layer 155_L may be formed on the gate semiconductor material layer 152_L. In other words, the gate semiconductor material layer 152_L is located between the barrier layer 136 and the gate electrode material layer 155_L.

As an example, the gate electrode material layer 155_L may be formed using a deposition process. For example, the gate electrode material layer 155_L can be formed using electron beam evaporation (E-beam evaporation), sputtering, physical vapor deposition (PVD), thermal chemical vapor deposition (thermal CVD), and low pressure chemical vapor deposition (LP-CVD), plasma-enhanced chemical vapor deposition (PE-CVD), or atomic layer deposition (ALD), etc., but is not limited thereto.

A hard mask material layer 156_L may be formed on the gate electrode material layer 155_L.

As an example, the hard mask material layer 156_L may be a spin-on hardmask layer (SOH). The spin-on hard mask material layer may be formed on the gate electrode material layer 155_L through a spin coating process.

The hard mask material layer 156_L may include silicon oxide, silicon nitride, silicon nitride, or a combination thereof.

Referring to FIG. 9, a photoresist pattern PR may be formed on the hard mask material layer 156_L.

First, a photoresist composition is coated on the hard mask material layer 156_L to form a photoresist film. As an example, the photoresist film may be formed by applying a photoresist composition on the hard mask material layer 156_L by spin coating, spray coating, dip coating, or knife edge coating, or by a printing method such as inkjet printing or screen printing and then drying the applied photoresist composition. That is, the photoresist film may be formed by coating a photoresist composition on the hard mask material layer 156_L and then curing it through a heat treatment process.

Next, a first baking process of heating the substrate 110 on which the photoresist film is formed may be performed. The first baking process may be performed at a temperature of about 80° C. to about 180° C. for about 30 seconds to about 3 minutes.

Next, the photoresist film is selectively exposed.

For example, examples of light that can be used in the exposure process include light with short wavelengths such as activating radiation i-line (wavelength 365 nm), KrF excimer laser (wavelength 248 nm), and ArF excimer laser (wavelength 193 nm) and light with a high energy wavelength such as EUV (Extreme UltraViolet; wavelength 13.5 nm) or E-Beam (electron beam). For example, the exposure light may be short-wavelength light having a wavelength range of about 5 nm to about 150 nm, and may be light having a high-energy wavelength such as EUV or E-Beam.

The exposed region of the photoresist film has a different solubility from the unexposed region of the photoresist film as a polymer is formed through a crosslinking reaction such as condensation between organometallic compounds.

Subsequently, a second baking process may be performed on the substrate 110. The second baking process may be performed at a temperature of about 120° C. to about 200° C. for about 30 seconds to about 3 minutes. By performing the second baking process, the exposed region of the photoresist film becomes difficult to dissolve in the developer.

Next, a photoresist pattern PR is formed by dissolving and removing the photoresist film corresponding to the unexposed region using a developer. For example, a photoresist pattern PR corresponding to a negative tone image is completed by dissolving the photoresist film corresponding to the unexposed region using an organic solvent such as 2-heptanone and then removing it.

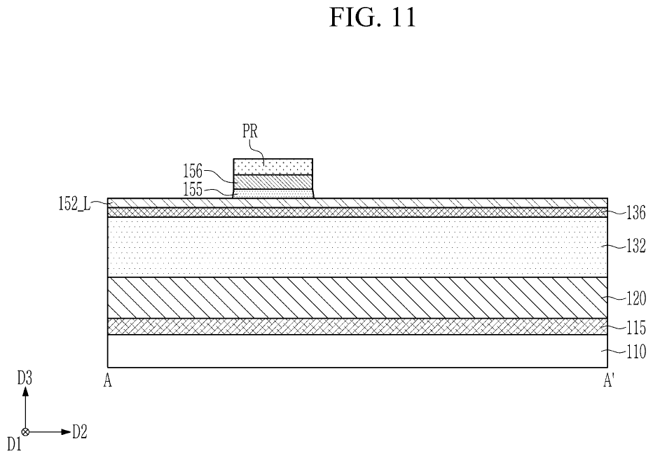

Referring to FIGS. 10 and 11, the hard mask material layer 156_L and the gate electrode material layer 155_L are etched using a photoresist pattern PR to form the hard mask layer 156 and the gate electrode layer 155.

For example, the hard mask material layer 156_L and the gate electrode material layer 155_L may be etched by dry etching using a first etching gas. The first etching gas may include a fluoride gas, and the fluoride gas may include, for example, CHF₃, CF₄, or a mixture thereof.

At this time, the hard mask material layer 156_L and the gate electrode material layer 155_L may be etched sequentially. Alternatively, the hard mask material layer 156_L may be etched first and then the gate electrode material layer 155_L may be etched. In this case as well, etching of the hard mask material layer 156_L and the gate electrode material layer 155_L may be performed using the same first etching gas.

In this way, as the gate electrode layer 155 is formed using the photoresist pattern PR and the gate semiconductor layer 152 is formed using the hard mask layer 156 as will be described later, the gate electrode layer 155 can be etched with a first etching gas, and the gate semiconductor layer 152 can be etched with a second etching gas, thereby increasing a degree of freedom in selecting the etching material for the gate electrode layer 155 and the gate semiconductor layer 152.

However, when the gate electrode layer 155 is etched with the first etching gas and the gate semiconductor layer 152 is etched with the second etching gas, by-products generated when the gate electrode layer 155 is etched with the first etching gas may affect and cause defects when the gate semiconductor layer 152 is etched with the second etching gas.

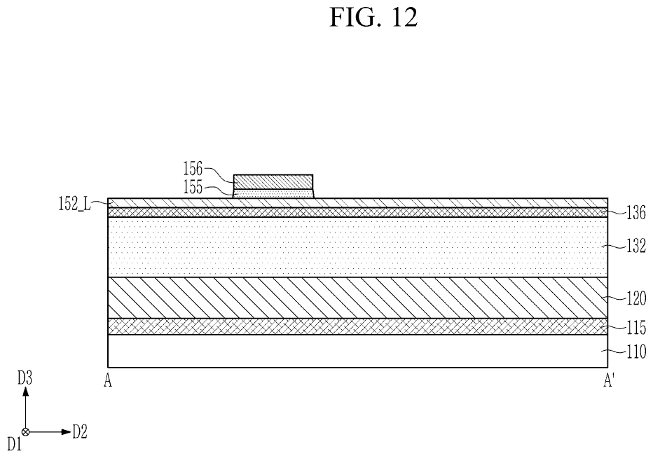

Referring to FIG. 12, after etching the gate electrode layer 155 with the first etching gas and before etching the gate semiconductor layer 152 with the second etching gas, by-products generated when the gate electrode layer 155 is etched with the first etching gas can be removed. Accordingly, the problem of defects caused by by-products caused by etching the dissimilar materials of the gate electrode layer 155 and the gate semiconductor layer 152 with different etching materials can be solved.

In this process, the photoresist pattern PR may be removed together.

For example, the removing of by-products or removal of the photoresist pattern PR may be accomplished through an ashing or strip process. In some implementations, the ashing process and the strip process may proceed sequentially. That is, an ashing process may be performed to remove the upper portion of the photoresist pattern PR through an oxygen (O₂) plasma treatment process or an ozone (O₃) treatment process, and then a strip process may be performed.

In some implementations, a process for cleaning the substrate 110 may be performed separately from the ashing process or strip process for removing the photoresist pattern PR.

As an example, the cleaning process may include a dry-cleaning process using, for example, NH₃ gas, NF₃ gas, or NF₃ plasma, or a wet cleaning process using HF or BOE. Thereafter, the substrate 110 may be cleaned using a cleaning solution such as ammonia water (NH₄OH).

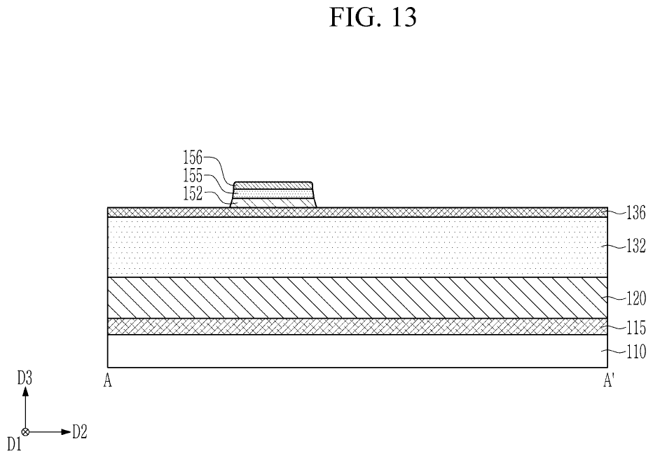

Referring to FIG. 13, the gate semiconductor material layer 152_L is etched using the hard mask layer 156 to form the gate semiconductor layer 152.

As an example, the gate semiconductor material layer 152_L may be patterned using the hard mask layer 156. Accordingly, the gate semiconductor layer 152 may have a pattern similar to that of the gate electrode layer 155. In other words, the gate semiconductor layer 152 and the gate electrode layer 155 can be self-aligned, and through this, alignment between the gate electrode layer 155 and the gate semiconductor layer 152 is easy and excellent. Because the loss of the hard mask layer 156 is small compared to the photoresist pattern PR, the pattern of the gate semiconductor layer 152 is precise.

As an example, the gate semiconductor material layer 152_L may be etched by dry etching using a second etching gas. The second etching gas is different from the first etching gas and may include chloride gas. For example, the chloride gas may include Cl₂, BCl₃, or a mixture thereof.

In order to minimize damage to the barrier layer 136 in the process of etching the gate semiconductor material layer 152_L, selective etching process conditions may be required to have a difference in etch rate between the gate semiconductor material layer 152_L and the barrier layer 136. For example, the barrier layer 136 made of AIGaN can be hardly etched, while the gate semiconductor material layer 152_L made of p-GaN can be easily etched. At this time, a surface oxidation etching method can be used by adding oxygen (O₂) to the etch gas. Accordingly, when the barrier layer 136 is not damaged and has a predetermined thickness, the channel layer 132 can have a high current density.

At this time, the hard mask layer 156 is partially etched according to the etching conditions when etching the gate semiconductor layer 152, and the hard mask layer 156 may have a shape in which the corners formed by the top surface US_156 and the side surface SW_156 are rounded. Since as the edge of the hard mask layer 156 have a rounded shape, the angle θ_177a formed by the lower surface BS_177a1 of the landing portion 177a1 of the first field dispersion layer 177a and the lower surface BS_177a3 of the connecting portion 177a3 can be adjusted, the generation of voids can be prevented when forming the first field dispersion layer 177a.

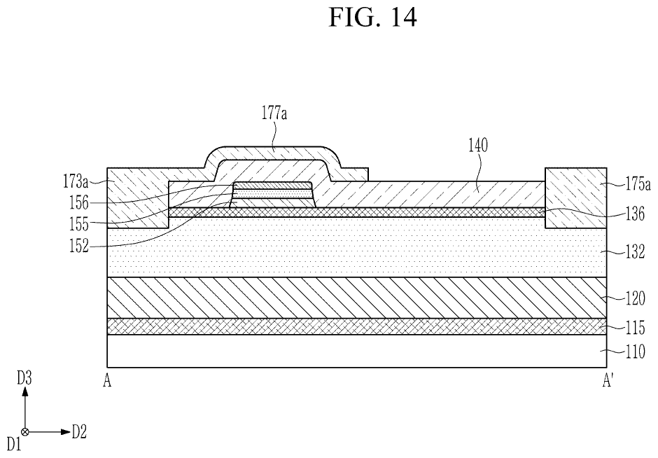

Referring to FIG. 14, a first protective layer 140 may be formed on the barrier layer 136, the gate semiconductor layer 152, and the gate electrode layer 155. The first protective layer 140 may be formed using a deposition process. The first protective layer 140 may include an insulating material. For example, the first protective layer 140 may include a material such as SiO₂, SiN, SiON, or Al₂O₃. The first protective layer 140 is shown as a single layer, but may be composed of multiple layers in some cases. At this time, the first protective layer 140 may be formed by sequentially depositing different materials. Alternatively, the first protective layer 140 may be formed of several layers with different characteristics by using the same material and varying deposition conditions. In particular, the portion of the first protective layer 140 adjacent to the barrier layer 136 may be made of an insulating material of much higher quality than other portions. This is to prevent electrons forming a channel from being trapped in the channel layer 132 under the barrier layer 136. The portion of the first protective layer 140 that is in contact with the barrier layer 136 may be made of SiO₂.

Next, the first protective layer 140 is patterned to form a trench, and the source electrode 173 and the drain electrode 175 can be formed within the trench. At this time, in the process of forming the trench, not only the first protective layer 140 but also the barrier layer 136 and the channel layer 132 may be patterned together. Additionally, the field dispersion layer 177 may be formed together in the process of forming the source electrode 173 and the drain electrode 175.

The source electrode 173 and the drain electrode 175 may be in ohmic contact with the channel layer 132. The region in contact with the source electrode 173 and the drain electrode 175 within the channel layer 132 may be doped at a relatively high concentration compared to other regions. For example, the channel layer 132 may be doped by an ion implant process, an annealing process, etc. However, it is not limited to this, and the doping process of the channel layer 132 may be performed through various other processes. The doping process of the channel layer 132 may be performed before forming the source electrode 173 and the drain electrode 175. In some cases, the channel layer 132 may not be doped.

Inside the channel layer 132, a two-dimensional electron gas 134 may be formed in a portion adjacent to the barrier layer 136. The two-dimensional electron gas 134 may be located at the interface between the channel layer 132 and the barrier layer 136. The two-dimensional electron gas 134 may be located in the drift region DTR between the source electrode 173 and the drain electrode 175. A depletion region DPR may be formed in the channel layer 132 by the gate semiconductor layer 152 having a different energy bandgap than the barrier layer 136. Accordingly, a semiconductor device may have normally-off characteristics. That is, the semiconductor device may be a normally-off high electron mobility transistor (HEMT). In the gate-off state, the two-dimensional electron gas 134 may be located in the drift region DTR excluding the depletion region DPR of the channel layer 132. In the gate-on state, the flow of the two-dimensional electron gas 134 continues within the depletion region DPR, and the two-dimensional electron gas 134 may be located entirely within the drift region DTR.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While this disclosure has been described in connection with what is presently considered to be practical implementations, it is to be understood that the disclosure is not limited to the disclosed implementations, but, on the contrary, is intended to cover various modifications and equivalent arrangements included within the spirit and scope of the appended claims.

What is claimed is:

1. A semiconductor device, comprising
a channel layer,
a barrier layer located on the channel layer, the barrier layer including a material having an energy bandgap different from a material of the channel layer,
a gate electrode layer located on the barrier layer and extending in a first direction, the first direction being parallel to an upper surface of the barrier layer,
a gate semiconductor layer between the barrier layer and the gate electrode layer, and
a source electrode and a drain electrode connected with the channel layer and spaced apart from the gate electrode layer in a second direction, the second direction being parallel to the upper surface of the barrier layer and intersecting the first direction,
wherein, in a cross-section cut in the second direction and in a third direction perpendicular to the upper surface of the barrier layer, an angle formed by a lower surface and a side surface of the gate electrode layer is greater than an angle formed by a lower surface and a side surface of the gate semiconductor layer.

2. The semiconductor device of claim 1, wherein
in the cross-section cut in the second direction and in the third direction,
the angle formed between the lower surface and the side surface of the gate electrode layer is 60° to 90°, and
the angle formed between the lower surface and the side surface of the gate semiconductor layer is 30° to 89°.

3. The semiconductor device of claim 1, wherein
a length of an upper surface of the gate electrode layer in the second direction is smaller than a length of the lower surface of the gate electrode layer in the second direction.

4. The semiconductor device of claim 1, wherein
a length of an upper surface of the gate semiconductor layer in the second direction is smaller than a length of the lower surface of the gate semiconductor layer in the second direction.

5. The semiconductor device of claim 1, wherein
a difference in length between the lower surface and an upper surface of the gate electrode layer in the second direction is smaller than a difference in length between the lower surface and an upper surface of the gate semiconductor layer in the second direction.

6. The semiconductor device of claim 1, wherein
the semiconductor device includes a hard mask layer on the gate electrode layer, and
in the cross-section cut in the second direction and in the third direction,
an edge formed by an upper surface and a side surface of the hard mask layer has a rounded shape.

7. The semiconductor device of claim 6, wherein
in the cross-section cut in the second direction and in the third direction,
an angle formed between the upper surface and the side surface of the hard mask layer decreases as a distance from the upper surface to the side surface of the hard mask layer in the third direction increases.

8. The semiconductor device of claim 6, wherein
a ratio of a length of the upper surface of the hard mask layer in the second direction and a length of the lower surface of the hard mask layer in the second direction is 9:10 to 9:12.

9. The semiconductor device of claim 6, wherein
a length of the lower surface of the hard mask layer in the second direction is smaller than a length of an upper surface of the gate electrode layer in the second direction.

10. The semiconductor device of claim 1, wherein the semiconductor device includes
a first protective layer covering the barrier layer and the gate electrode layer, and
a first field dispersion layer located on the first protective layer, connected with the source electrode, and overlapped with the gate electrode layer in the third direction, and
wherein the first field dispersion layer includes
an overlapping portion overlapped with the gate electrode layer in the third direction,
a landing portion located on both sides of the overlapping portion in the second direction and having a closer distance from the upper surface of the barrier layer in the third direction than the overlapping portion, and
a connection portion connecting the overlapping portion and the landing portion.

11. The semiconductor device of claim 10, wherein
in the cross-section cut in the second direction and in the third direction,
an angle formed by a lower surface of the landing portion and a lower surface of the connection portion is 90° to 150°.

12. A semiconductor device, comprising
a channel layer,
a barrier layer located on the channel layer, the barrier layer including a material having an energy bandgap different from a material of the channel layer,
a gate electrode layer located on the barrier layer and extending in a first direction, the first direction being parallel to an upper surface of the barrier layer,
a gate semiconductor layer between the barrier layer and the gate electrode layer,
a hard mask layer on the gate electrode layer, and
a source electrode and a drain electrode connected with the channel layer and spaced apart from the gate electrode layer in a second direction, the second direction being parallel to the upper surface of the barrier layer and intersecting the first direction,
wherein, in a cross-section cut in the second direction and in a third direction perpendicular to the upper surface of the barrier layer,
an edge formed by an upper surface and a side surface of the hard mask layer has a rounded shape, and
a length of a lower surface of the gate electrode layer in the second direction is smaller than a length of an upper surface of the gate semiconductor layer in the second direction and a length of a lower surface of the hard mask layer in the second direction.

13. The semiconductor device of claim 12, wherein
an edge formed by the lower surface and the side surface of the hard mask layer has a rounded shape.

14. The semiconductor device of claim 13, wherein
in the cross-section cut in the second direction and in the third direction,
(i) the rounded shape of the edge formed by the upper surface and the side surface of the hard mask layer is gentler than the rounded shape of the edge formed by the lower surface and the side surface of the hard mask layer, and
(ii) the rounded shape of the edge formed by the lower surface and the side surface of the hard mask layer is steeper than the rounded shape of the edge formed by the upper surface and the side surface of the hard mask layer.

15. The semiconductor device of claim 13, wherein
a length of the upper surface of the hard mask layer in the second direction is smaller than a length of the lower surface of the hard mask layer in the second direction.

16. The semiconductor device of claim 12, wherein
a length of an upper surface of the gate electrode layer in the second direction is greater than a length of the lower surface of the gate electrode layer in the second direction.

17. The semiconductor device of claim 12, wherein
a length in the second direction at a midpoint between the upper surface and the lower surface of the gate electrode layer is smaller than (i) a length of the upper surface of the gate electrode layer in the second direction and (ii) a length of the lower surface of the gate electrode layer in the second direction.

18. The semiconductor device of claim 12, wherein
a length in the second direction at a midpoint between the upper surface and the lower surface of the gate electrode layer is smaller than a length of the upper surface of the gate electrode layer in the second direction, and
a length of the upper surface of the gate electrode layer in the second direction is smaller than a length of the lower surface of the gate electrode layer in the second direction.

19. A method for manufacturing semiconductor device, comprising
forming a channel layer on a substrate,
forming a barrier layer on the channel layer, the barrier layer including a material having an energy bandgap different from a material of the channel layer,
sequentially forming a gate semiconductor material layer, a gate electrode material layer, and a hard mask material layer on the barrier layer,
forming a photoresist pattern on the hard mask material layer, etching the hard mask material layer and the gate electrode material layer with a first etching gas using the photoresist pattern to form a hard mask layer and a gate electrode layer,
removing the photoresist pattern,
forming a gate semiconductor layer based on etching the gate semiconductor material layer with a second etching gas different from the first etching gas using the hard mask layer, and
forming a source electrode and a drain electrode connected with the channel layer and spaced apart from the gate electrode layer.

20. The method of claim 19, wherein
the first etching gas includes a fluoride gas, and
the second etching gas includes a chloride gas.
